(19) United States
(12) Patent Application Publication
(10) Pub. No.: US 2012/0049332 A1
(43) Pub. Date: Mar. 1, 2012

(54) SEMICONDUCTOR PACKAGE AND METHOD FOR MANUFACTURING THE SAME

(75) Inventors: Jen-Chuan Chen, Bade City (TW); Hui-Shan Chang, Jhongli City (TW); Wen-Hsiung Chang, Hsinchu City (TW); Wei-Nung Chang, Bade City (TW)

(73) Assignee: ADVANCED SEMICONDUCTOR ENGINEERING, INC., Kaohsiung (TW)

(21) Appl. No.: 13/181,278

(22) Filed: Jul. 12, 2011

(30) Foreign Application Priority Data
Aug. 25, 2010 (TW) 99128498

(51) Int. Cl. H01L 23/58; H01L 21/82

(52) U.S. Cl. 257/632; 438/113; 257/E23.002; 257/E21.602

(57) ABSTRACT

A semiconductor package and method for making the same are provided, wherein a lower chip having a plurality of conductive structures is bonded to an upper surface of a package substrate and a plurality of matrix walls are formed on the upper surface for surrounding the lower chip, such that an overcoat layer covering the matrix walls and the lower chip can be approximately removed after performing a grinding process to the lower chip to expose a plurality of conductive vias of the lower chip. The cleaning step for removing the residue of overcoat layer can be omitted, and the processing yield and the processing efficiency can be improved. The semiconductor package and the method is particularly suitable for stacking a large dimensional upper chip on a relatively small dimensional lower chip.

### CROSS-REFERENCE TO RELATED APPLICATIONS

This application claims the benefit of Taiwan application Serial No. 99128498, filed Aug. 25, 2010, the subject matter of which is incorporated herein by reference.

### BACKGROUND OF THE INVENTION

1. Field of the Invention

The present invention relates to the field of semiconductor packaging, and, more particularly, to 3-D semiconductor packaging.

2. Description of Related Art

One technique for forming a three dimensional package having two or more vertically stacked chips includes the use of through silicon vias (TSV), i.e. conductive vias formed in the die which provide for a conductive path between a lower surface of the die to an upper surface. There are various methods for forming through silicon vias and connecting additional die to the through silicon vias. However, conventional approaches can leave unwanted residues thereby contaminating the through silicon vias.

### SUMMARY OF THE INVENTION

One aspect of the disclosure relates to a semiconductor package. In one embodiment, the semiconductor package includes a substrate having a plurality of walls formed on an upper surface thereof; a first chip disposed on the substrate, the first chip surrounded by the walls; and a second chip coupled to the first chip. The first chip includes a plurality of conductive vias to electrically connect the first chip with the second chip. In this embodiment, the walls and the upper surface together form a cavity, the first chip is disposed in the cavity, and the cavity is filled with an underfill. In an embodiment, a molding compound is disposed on the substrate to substantially cover the walls and the second chip. In other embodiments, the molding compound is not used. The semiconductor package is particularly suitable for stacking a large dimensional upper chip on a relatively small dimensional lower chip. However, in some embodiments the upper chip is smaller than the lower chip.

Another aspect of the disclosure relates to manufacturing methods. In one embodiment, a manufacturing method includes: (1) providing a substrate, wherein the substrate has an upper surface and a matrix structure disposed on the upper surface, wherein the matrix structure and the upper surface together define a plurality of cavities; (2) bonding a plurality of first chips, each to a respective cavity, wherein each of the first chips has a plurality of conductive structures therein; (3) placing a first underfill between each of the first chips and the substrate; (4) forming an overcoat layer on a carrier, the overcoat layer covering the substrate and the first chips; (5) thinning the overcoat layer and the first chips from a top surface of the overcoat layer; (6) exposing an end of each of the conductive structures in each of the first chips, to form a plurality of conductive vias; (7) bonding a plurality of second chips, each to a respective first chip; (8) placing a second underfill between each of the second chips and a respective first chip; and (9) cutting the substrate into a plurality of package units, wherein the substrate is cut into a plurality of package substrates.

### BRIEF DESCRIPTION OF THE DRAWINGS

FIG. 1 is a cross-sectional view of a semiconductor package according to an embodiment of the present invention.

FIGS. 2A to 2L illustrate a manufacturing process according to an embodiment of the present invention; and

FIGS. 3 to 5 are cross-sectional views of other embodiments of the present invention.

Common reference numerals are used throughout the drawings and the detailed description to indicate the same elements. The present invention will be more apparent from the following detailed description taken in conjunction with the accompanying drawings.

### DETAILED DESCRIPTION

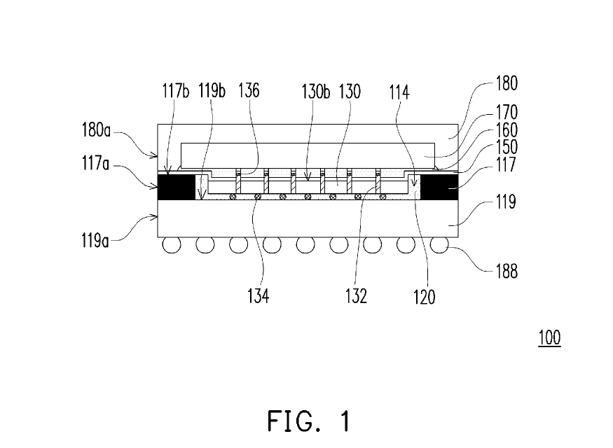

FIG. 1 illustrates a semiconductor package 100 according to an embodiment of the present invention. As shown, the semiconductor package 100 includes a substrate 119, a first chip 130, a first underfill 120, a second chip 170 and a second underfill 160. The substrate 119 has a plurality of walls 117 surrounding the first chip 130 formed on an upper surface 119b. The walls 117 and the upper surface 119b of the substrate 119 together define a cavity 114. The first chip 130 is disposed in the cavity 114 which is filled with the first underfill 120. The second chip 170 is disposed on the first chip 130 and electrically connected to the first chip 130 through a plurality of conductive vias 132. The first chip 130 is bonded to the substrate 119 using a plurality of bumps 134. The second underfill 160 is disposed between the second chip 170 and the first chip 130.

The semiconductor package 100 may further comprise a surface finish layer 136 disposed on an end of each of the conductive vias 132 protruding from a first surface 130a of the first chip 130, as shown. The walls 117 may be substantially thicker than the first chip 130. In an embodiment, the thickness of the first chip chip 130 is substantially equal to or less than 50 um. Furthermore, a first surface 130b of the first chip 130 may be about 3-10 um below a top surface 117b of the walls 117. Additionally, the semiconductor package 100 may further comprise a passivation layer 150 disposed on the first chip 130 and a molding compound 180 disposed on the substrate 119 to cover the walls 117 and the second chip 170. Moreover, a side surface 180a of the molding compound 180, a side surface 117a of the matrix wall 117 and a side surface 119a of the package substrate 119 can be substantially aligned with one another. A plurality of solder balls 188 may be formed on the bottom of the package substrate 119.

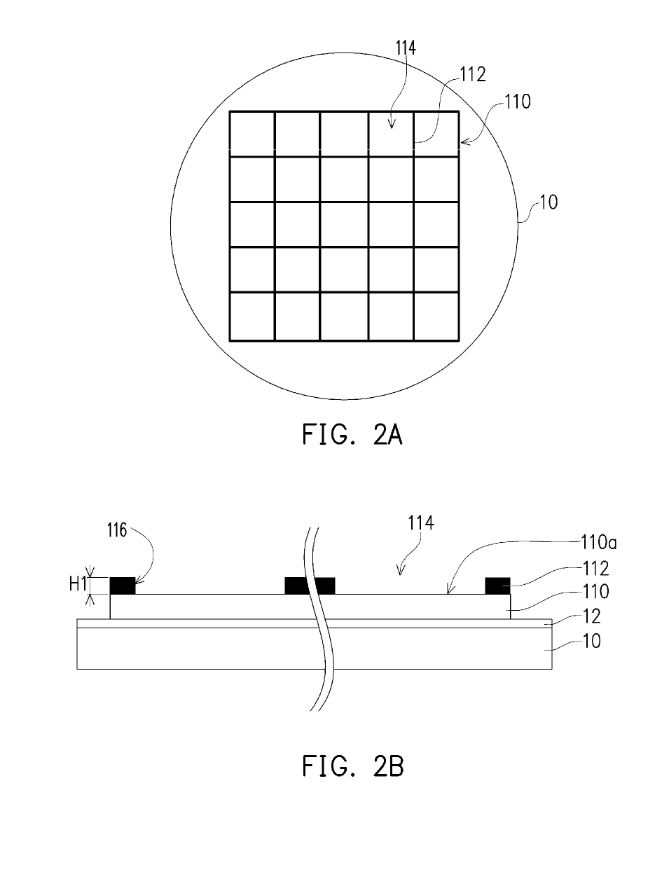

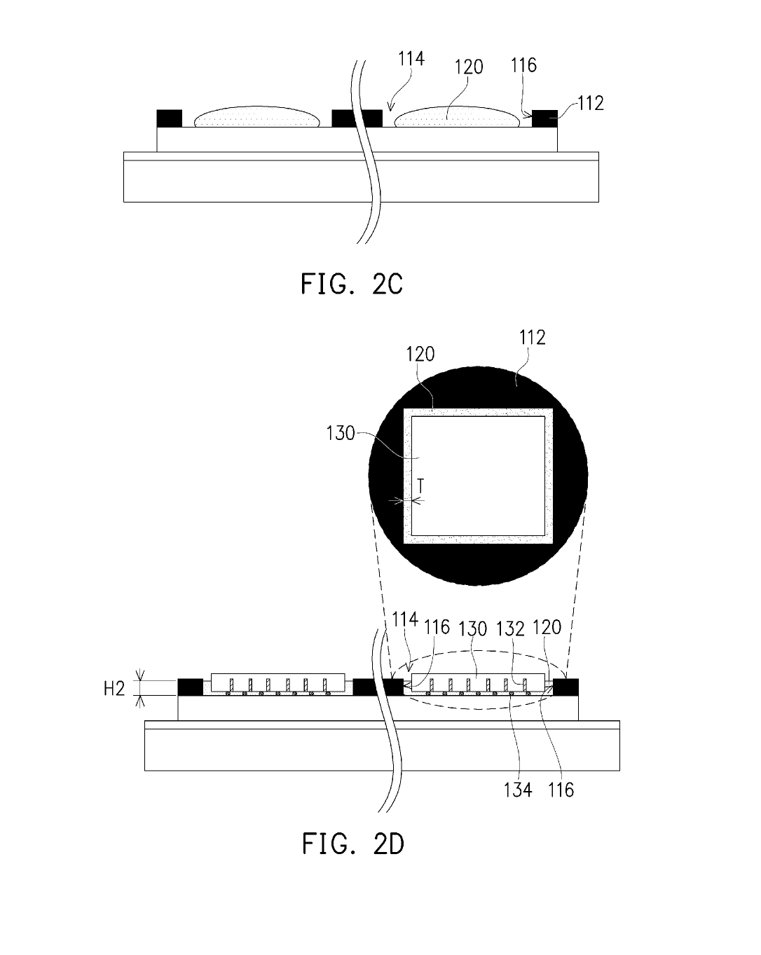

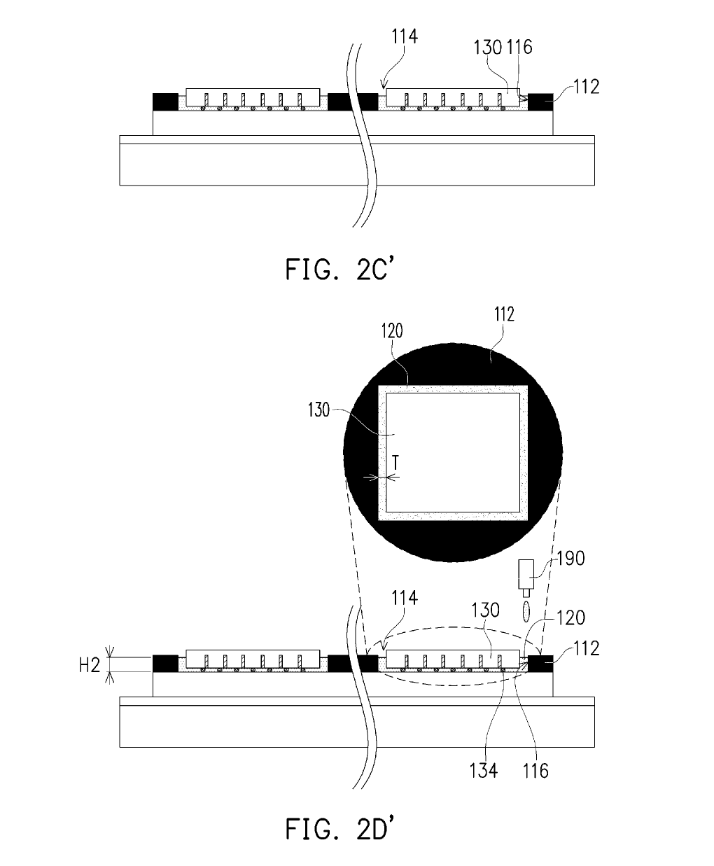

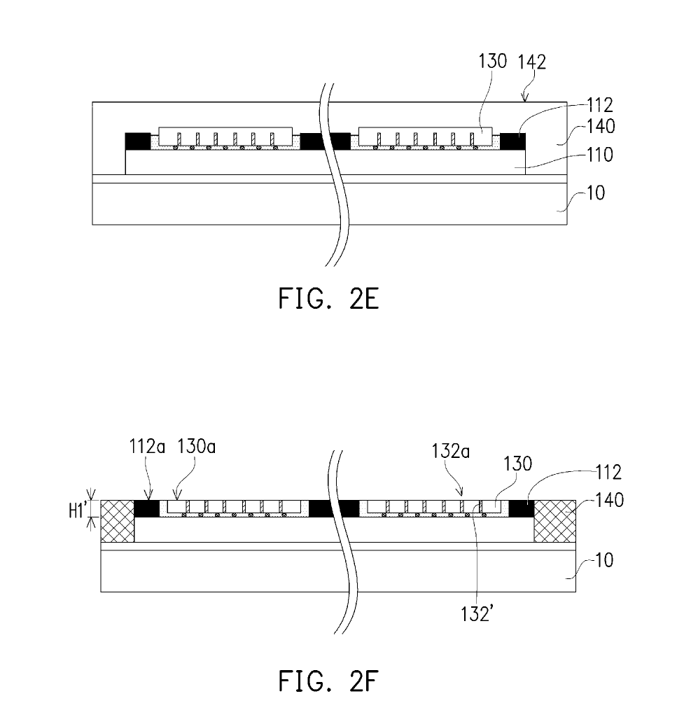

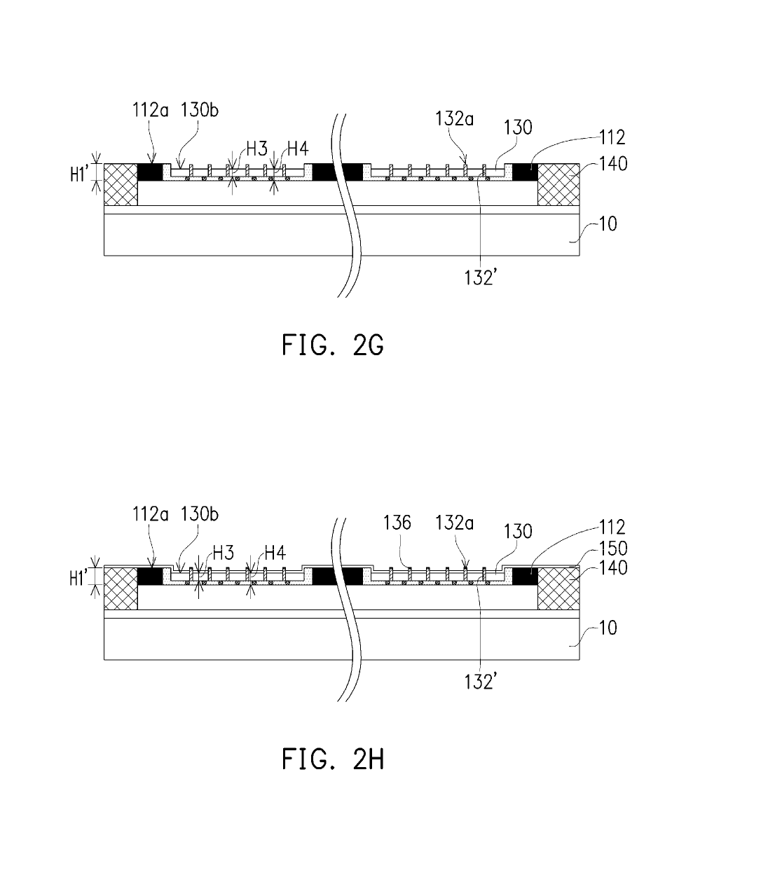

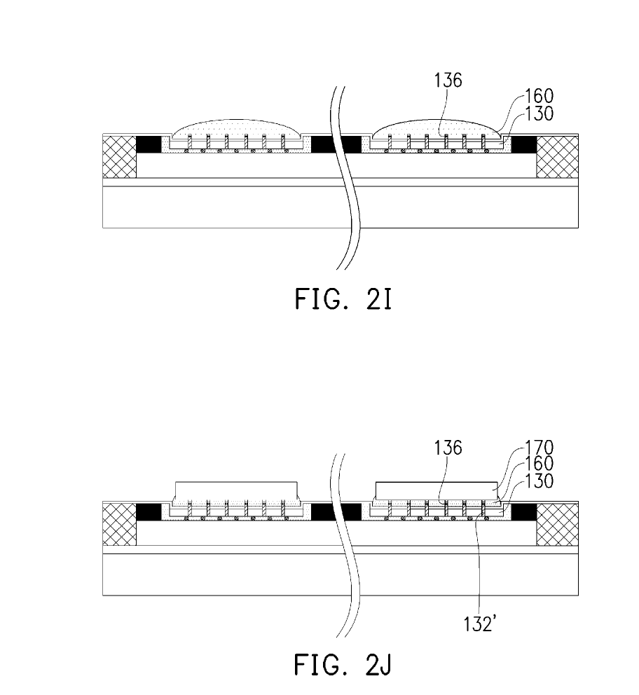

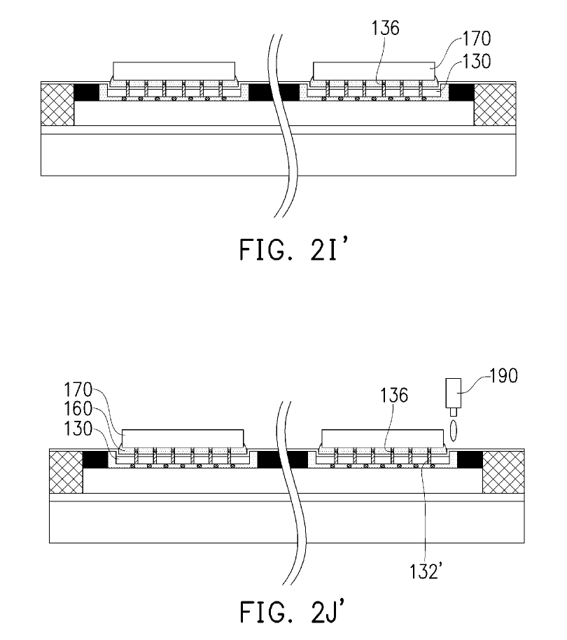

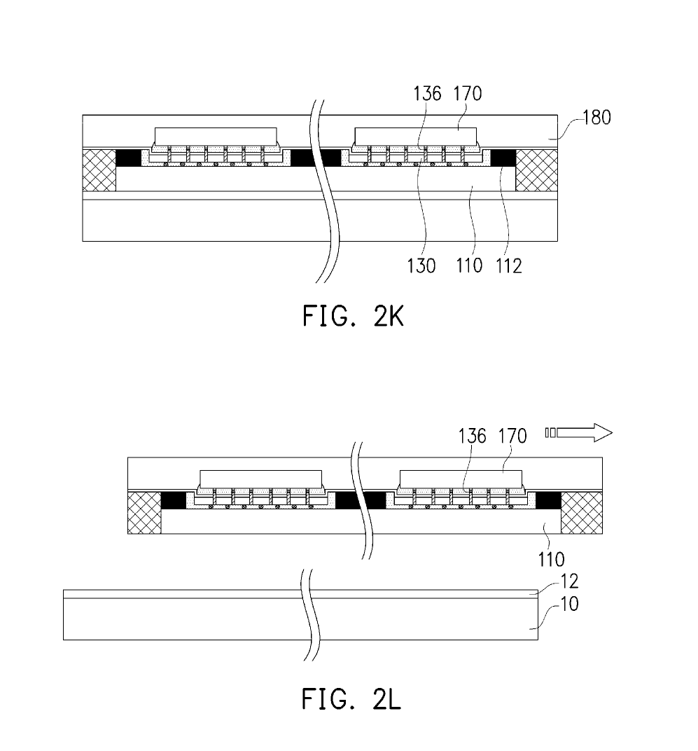

Methods for manufacture will now be described. Referring to FIG. 2A and FIG. 2B, a top view and a cross-sectional view of a structure useable in the manufacturing process are illustrated, respectively. As shown, a substrate 110 is disposed on a carrier 10. In this embodiment, the substrate 110 may be a printed circuit board or other type of substrate. The carrier 10 is provided with an adhesion layer 12 thereon to adhere the substrate 110 to the carrier 10. The substrate 110 has an upper surface 110a opposite to the carrier 10 and a matrix structure 112 is formed on the upper surface 110a. The matrix structure 112 creates a plurality of cavities 114, formed by the upper surface 110a of the substrate 110 and a side surface 116 of the matrix structure 112. The solder mask layer of the substrate 110 can be increased beyond its usual thickness to form the matrix structure 112 with a sufficient height. Advantageously, forming the matrix structure 112 from the solder mask layer of the substrate requires no additional processing. In other embodiments, the matrix structure 112 can be formed using a non-conductive polymer, such as epoxy, polyimide (PI), benzocyclobutene (BCB), etc. by additional processes. As illustrated, the height of the matrix structure 112 is depicted as H1. In this embodiment, the height of H1 is greater than a final height (depicted as H4 in FIG. 2H) of the first chip 130, and the final height of the first chip 130 is equal to a sum of a final thickness of the first chip 130 (depicted as H3 in FIG. 2H) and a thickness of bumps 134 (as shown in FIG. 2D). In this embodiment, the final thickness of the first chip 130 is equal to or less than about 50 um.

Referring to FIG. 2C, a first underfill 120 is formed in each of the cavities 114. Referring to FIG. 2D, the plurality of first chips 130 are then disposed into the corresponding cavities 114, respectively, wherein each of the first chips 130 has a plurality of conductive structures 132 and a plurality of conductive bumps 134, and the first chips 130 are bonded to the substrate 110 by thermal compression bonding of the bumps 134 to corresponding contact pads provided on the substrate 110. In this embodiment, the first chips 130 are active dice, such as, processor dice, memory dice, etc. and the conductive structures 132 are conductive cylinders embedded in the first chips 130. However, in other embodiments, the first chips 130 also can be interposers. After the first chips 130 are bonded to the substrate 110, the first underfill 120 fills the gap between each of the first chips 130 and the substrate 110 and encapsulates bumps 134. In this embodiment, the first underfill 120 fills a part of a portion between the first chips 130 and the side surface 116 of the matrix structure 112. The thickness of the first underfill 120 depicted as H2. In this embodiment, the thickness of H2 is larger than the final height (depicted as H4 in FIG. 2H) of the first chip 130, and the final height of the first chip 130 is equal to the sum of the final thickness of the first chip 130 and the thickness of bumps 134. In this embodiment, the final thickness of the first chip 130 is substantially equal to or less than 50 um. In this embodiment, the height of H1 is greater than the thickness of H2. However, in other embodiments, the thickness of H2 may be about equal to the height of H1.

It is to be understood that the two fabrication steps as shown in FIGS. 2C and 2D, respectively, and described above, can alternatively be done in reverse order. Referring to FIGS. 2C′ and 2D′, the first chips 130 may be disposed in the corresponding cavities 114 first (as shown in FIG. 2C′), and then the first underfill 120 can be placed into the cavities 114 by a dispensing head 190 (as shown in FIG. 2D′), such that the first underfill 120 fills the gap between each of the first chip 130 and the substrate 110 and encapsulates the bumps 134.

Referring to FIGS. 2D and 2D′, there is a tolerance T between the first chips 130 and the side surfaces 116 of the matrix structures 112. FIGS. 2D and 2D′ further show a partial top view of the structure depicting the tolerance T between the first chips 130 and the side surfaces 116 of the matrix structure 112. In this embodiment, the tolerance T is about 1 millimeter (mm).

FIG. 2E illustrates an overcoat layer 140 formed on the carrier 10 which covers the substrate 110, the matrix structure 112 and the first chips 130. The overcoat layer 140 provides a flat surface for a subsequent grinding process. In this embodiment, the overcoat layer 140 is of the same material as the adhesion layer 12, formed between the substrate 110 and the carrier 10 (shown in FIG. 2B). In this embodiment, the overcoat layer 140 is formed by an epoxy material, an acrylic material, etc. In other embodiments, the overcoat layer can be formed by a polymer material, such as, polyimide (PI), benzocyclobutene (BCB), etc.

FIG. 2F illustrates the overcoat layer 140, the matrix structure 112 and the first chips 130 thinned by grinding from a top surface 142 of the overcoat layer 140 until an end 132a of each of the conductive structures 132 of each of the first chips 130 are exposed. Accordingly, the conductive structures 132 are exposed and become a plurality of conductive vias 132′. At this point, the top surface 112a of the matrix structure 112 and the top surface 130a of each of the first chips 130 are substantially coplanar. As shown, the height of the matrix structure 112 is depicted as H1′. In this embodiment, the height of the matrix structure 112 is maintained during the thinning process, that is, H1′ is equal to H1. In other embodiments, the height of the matrix structure 112 is reduced during the thinning process, that is, H1′ is less than H1. Importantly, the overcoat layer 140 above the matrix structure 112 and the first chips 130 is substantially entirely removed eliminating the need for a cleaning step to remove any residue.

FIG. 2G shows the conductive vias 132′ protruding from a first surface 130b, the result of etching the top surface 130a of each of the first chips 130 until a final desired chip thickness H3 is achieved. In this embodiment, the final chip thickness H3 is equal to or less than about 50 μm. A final height H4 of the first chip 130 is equal to the sum of the final thickness H3 of the first chip 130 and the thickness of bumps 134.

Referring to FIG. 2H, in this embodiment, the thickness difference between the top surface 112a of the matrix structure 112 and the first surface 130b of each of the first chips 130 is equal to about 3˜10 um. In addition, a passivation layer 150 can be formed to cover the matrix structure 112 and the first surface 130b of each of the first chips 130. Additionally, the end 132a of each of the conductive vias 132′ may protrude from the passivation layer 150. In this embodiment, the passivation layer 150 is made by a non-conductive polymer such as polyimide (PI), epoxy or benzocyclobutene (BCB). In this embodiment, the first passivation layer 150 is a photo sensitive polymer such as benzocyclobutene (BCB), and is formed by spin coating or spray coating. A surface finish layer 136 is formed on the end of each of the conductive vias 132a. In this embodiment, the surface finish layer 136 is a metal layer or a alloy layer, such as a Nickel layer, a Nickel/Gold layer, a Nickel/Palladium/Gold, etc.

Referring to FIG. 2I, a second underfill 160 is formed over the first chips 130. And, referring to FIG. 2J, a plurality of second chips 170 are correspondingly bonded to the conductive vias 132′ of the first chips 130. After bonding the second chips 170 to the first chips 130, the second underfill 160 filled the gap between each of the first chips 130 and the corresponding second chip 170.

It is to be understood that the two steps as shown in FIGS. 2I and 2J, respectively, and described above, can alternatively be done in reverse order. Referring to FIGS. 2I′ and 2J′, the second chips 170 may be bonded to the corresponding first chips 130 first (as shown in FIG. 2I′), and then the underfill material can be disposed in the gap between the first chips 130 and the corresponding second chips 170 by the dispensing head 190 to form the second underfill 160 (as shown in FIG. 2J′).

Next, referring to FIG. 2K, a molding compound 180 may be used to cover the substrate 110, the matrix structure 112, the first 130 and the second chip 170. In other embodiments of the present invention, the molding compound 180 is not used.

Referring to FIG. 2L, the substrate 110 is released from the carrier 10 by detaching the bottom of the substrate 110 from the adhesion layer 12 on the carrier 10. Referring to FIG. 1 again, the substrate 110 is sawed to obtain a plurality of semiconductor packages 100, wherein the substrate 110 is sawed into a plurality of substrates 119 and the matrix structure 112 is sawed into a plurality of walls 117 surrounding their corresponding first chips 130. Moreover, solder balls 188 are formed on the bottom of the package substrate 119. In addition, if the molding compound 180 is used in the aforementioned process, the molding compound 180 can be sawed together with the substrate 110, such that a side surface 180a of the molding compound 180, a side surface 117a of the matrix wall 117 and a side surface 119a of the package substrate 119 are aligned with one another.

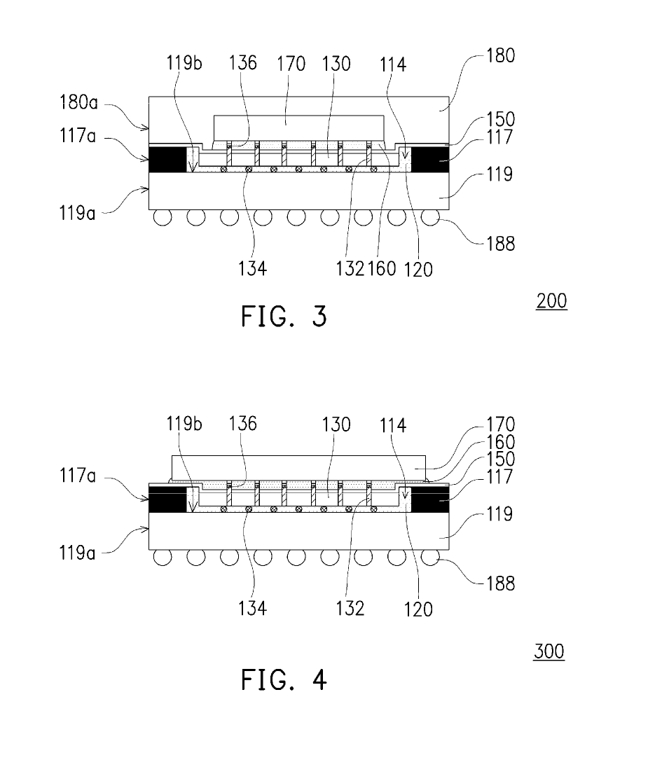

Referring to FIG. 3, a cross-sectional view showing a packaging structure according to an embodiment of the present invention is illustrated. The package structure 200 is similar to the semiconductor package 100 except that the dimension of the second chip 170 is smaller than that of the first chip 130. The package structure 200 can be formed by performing the above process, and so the details are not repeated hereinafter.

Referring to FIG. 4, a cross-sectional view showing a packaging structure according to another embodiment of the present invention is illustrated. The package structure 300 is similar to the semiconductor package 100 except that the package structure 300 is provided without molding compound. When performing the process of the above embodiment, the step of forming the molding compound 180 is omitted.

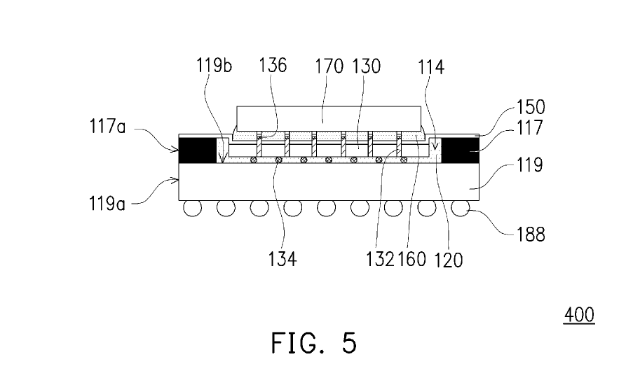

Referring to FIG. 5, a cross-sectional view showing a packaging structure according to further another embodiment of the present invention is illustrated. The package structure 400 is similar to the package structure 200 of the above embodiment except that the package structure 400 is provided without molding compound. When performing the process of the above embodiment, the step of forming the molding compound 180 is omitted.

While the invention has been described and illustrated with reference to specific embodiments thereof, these descriptions and illustrations do not limit the invention. It should be understood by those skilled in the art that various changes may be made and equivalents may be substituted without departing from the true spirit and scope of the invention as defined by the appended claims. The illustrations may not necessarily be drawn to scale. There may be distinctions between the artistic renditions in the present disclosure and the actual apparatus due to manufacturing processes and tolerances. There may be other embodiments of the present invention which are not specifically illustrated. The specification and the drawings are to be regarded as illustrative rather than restrictive. Modifications may be made to adapt a particular situation, material, composition of matter, method, or process to the objective, spirit and scope of the invention. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A semiconductor package, comprising:
a substrate having a plurality of walls formed on an upper surface thereof;
a first chip disposed on the substrate, the first chip surrounded by the walls; and
a second chip coupled to the first chip.

2. The semiconductor package of claim 1, wherein the first chip has a plurality of conductive vias formed therein.

3. The semiconductor package of claim 2, wherein the conductive vias electrically connect the first chip and the second chip.

4. The semiconductor package of claim 2, wherein ends of the conductive vias protruding from the first chip are covered with a surface finish layer.

5. The semiconductor package of claim 1, wherein the walls and the upper surface together form a cavity which is filled by a first underfill.

6. The semiconductor package of claim 1, wherein the second chip is larger than the first chip.

7. The semiconductor package of claim 1, wherein at least a portion of the second chip is located above the walls.

8. The semiconductor package of claim 1, wherein the first chip is equal to or less than about 50 μm in thickness.

9. The semiconductor package of claim 1, wherein each of the plurality of walls is substantially thicker than that of the first chip.

10. The semiconductor package of claim 9, wherein the first chip is disposed about 3 to 10 μm below a top surface of the walls.

11. The semiconductor package of claim 1, further comprising a molding compound disposed on the substrate to substantially cover the walls and the second chip.

12. The semiconductor package of claim 11, wherein a side surface of the molding compound, a side surface of the walls, and a side surface of the substrate are substantially aligned with one another.

13. The semiconductor package of claim 1, further comprising a underfill disposed between the second chip and the first chip.

14. The semiconductor package of claim 1, wherein the second chip is smaller than the first chip.

15. The semiconductor package of claim 5, further comprising a passivation layer substantially covering the first chip, the walls, and the first underfill.

16. A semiconductor package, comprising:
a substrate having a plurality of walls formed on an upper surface thereof, the walls and the upper surface together forming a cavity;
a first chip disposed in the cavity, the cavity with the first chip disposed therein filled with an underfill; and
a second chip coupled to the first chip.

17. The semiconductor package of claim 16, wherein the second chip is larger than the first chip and at least a portion of the second chip is located above the walls.

18. A method for making a semiconductor package, comprising:
providing a substrate, wherein the substrate has an upper surface and a matrix structure disposed on the upper surface, wherein the matrix structure and the upper surface together define a plurality of cavities;
bonding a plurality of first chips, each to a respective cavity, wherein each of the first chips has a plurality of conductive structures therein;
placing a first underfill between each of the first chips and the substrate;
forming an overcoat layer on a carrier, the overcoat layer covering the substrate and the first chips;
thinning the overcoat layer and the first chips from a top surface of the overcoat layer;
exposing an end of each of the conductive structures in each of the first chips, to form a plurality of conductive vias;
bonding a plurality of second chips, each to a respective first chip;
placing a second underfill between each of the second chips and a respective first chip; and
cutting the substrate into a plurality of package units, wherein the substrate is cut into a plurality of package substrates.

19. The method as claimed in claim 18, wherein the first underfill is formed in the cavities before the first chips are bonded to the substrate.

20. The method as claimed in claim 18, wherein the first underfill is formed in the cavities after the first chips are bonded to the substrate.
